(19) United States
(12) Patent Application Publication
(10) Pub. No.: US 2018/0108642 A1
(43) Pub. Date: Apr. 19, 2018

(54) INTERPOSER HEATER FOR HIGH BANDWIDTH MEMORY APPLICATIONS

(71) Applicant: GLOBALFOUNDRIES Inc., Grand Cayman (KY)

(72) Inventors: Wolfgang SAUTER, Burke, VT (US); Igor ARSOVSKI, Williston, VT (US)

(21) Appl. No.: 15/292,552

(22) Filed: Oct. 13, 2016

(51) Int. Cl. H01L 25/18; H01L 25/00; H01L 23/34; G11C 5/02

(52) U.S. Cl. CPC H01L 25/18; G11C 5/02; H01L 23/345; H01L 25/50

(57) ABSTRACT

A method for integrating heaters in high bandwidth memory (HBM) applications and the related devices are provided. Embodiments include forming a silicon (Si) interposer over a substrate; forming HBM and an integrated circuit (IC) over the Si interposer; forming a heater on the Si interposer in a space between the HBM and Si interposer; and utilizing one or more temperature sensors in the HBM to monitor a temperature of the HBM.

### TECHNICAL FIELD

The present disclosure relates to semiconductor fabrication. In particular, the present disclosure relates to an interposer heater integrated into applications that include high bandwidth memory (HBM) modules with logic chips in the 14 nanometer technology node and beyond.

### BACKGROUND

Prior semiconductor packaging devices have integrated heaters and interposers. However, existing heaters are only used for general heating. For example, a silicon carrier employed in wafer probe and electrical test application die rework includes a heater to facilitate with the removal, attachment and testing of electronic components.

Currently, there are no devices with controlled heating based on ambient environmental and component temperatures. Next generation networking and radio based systems require tremendous bandwidth (e.g., several terabytes per second) between the processor and memory. HBM is an up-front solution in the industry today which addresses this bandwidth performance requirement. FIG. 1A illustrates in top view, a substrate 101 which serves as a carrier for additional device components formed over an upper surface of the substrate 101. FIG. 1B is an exploded side view of the device illustrated in FIG. 1A. The substrate 101 is a typical package substrate, such as organic build-up or ceramic and can be formed of a variety of sizes such as 40×40 millimeter (mm). An interposer 103 is disposed over the substrate 101 and can be formed of a Si based material and have a 26×20 mm size. An IC 105 and HBM 107 are disposed over the interposer 103. The IC 105 can include an ASIC and have a 20×20 mm size and operates over a wide temperature range of −40° C. to 125° C. The HBM can include stacked dynamic random-access memory (DRAM) chips. The HBM 107 has a fairly small input/output (I/O) area (e.g., 3×6 mm) and a much larger body size of 8×12 mm. Although not illustrated, a plurality of HBM 107 can be positioned on either or both sides of the IC 105. The IC 105 is connected to the HBM with the interposer 103 due to the high number of signals between these two components. FIG. 2 is a partial top view of the device in FIG. 1A. FIG. 2 includes a plurality of signal lines/wires 201 between the HBM 107 and the IC 105.

Although ASIC technology can operate over a temperature range of −40° C. to 125° C., HBM only functions properly between 0° C. and 95° C. This is an insufficient range for certain environmental conditions, such as outside operation in cell phone towers located in colder climates. At the lower temperature limit (e.g., 0° C.), the environmental conditions may be such that the HBM 107 is much colder during off and dormant conditions. Further, at upper temperature limits of HBM 107 (e.g., 95° C.) it is very difficult to cool the HBM since it is in close proximity to a very hot, high powered IC 105.

A need therefore exists for methodology enabling heater integration that provides targeted heating at specific locations to ensure functionality in adverse environmental climates and the resulting devices.

### SUMMARY

An aspect of the present disclosure is an integrated heater for HBM applications that provides controlled heating based on ambient environmental and component temperatures at a very specific location to ensure functionality. The present disclosure provides a pre-heat function in the interposer to enable the HBM to operate properly at start-up. The present disclosure further provides a pre-heat function for the HBM through dynamic power with targeted activation.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming a Si interposer over a substrate; forming HBM and an integrated circuit (IC) over the Si interposer; forming a heater on the Si interposer in a space between the HBM and Si interposer; and utilizing temperature sensors in the HBM to monitor a temperature of the HBM.

Aspects of the present disclosure include forming the heater by forming resistance lines on the Si interposer in the space between the HBM and Si interposer. Other aspects include an output of the one or more temperature sensors in the HBM causing activation of the heater directly. Further aspects include forming a user operated register in the HBM for setting and adjusting a temperature of the HBM. Additional aspects include forming one or more temperature sensors in the IC. Yet further aspects include an output of the one or more temperature sensors in the IC that causes activation of the heater directly. Other aspects include forming wiring between the HBM and IC. Still further aspects include connecting the heater to power and ground connections.

Another aspect of the present disclosure is a method forming a Si interposer over a substrate; forming HBM and an IC over the Si interposer; utilizing one or more temperature sensors in the HBM to monitor a temperature of the HBM; and generating dummy reads to idle areas of the HBM or non-utilized bandwidth areas of the HBM to generate heat in the idle areas or non-utilized bandwidth areas to a pre-determined temperature.

Aspects include providing up to date temperature readings by the one or more temperature sensors to permit intelligent heating of the idle areas or non-utilized bandwidth areas.

Another aspect of the present disclosure is a Si interposer formed over a substrate; HBM and an IC formed over the Si interposer; one or more temperature sensors disposed in the HBM to monitor a temperature of the HBM, wherein the interface of the HBM is configured to generate dummy reads to idle areas of the HBM or non-utilized bandwidth areas of the HBM to generate heat in the idle areas or non-utilized bandwidth areas to a pre-determined temperature.

Yet another aspect of the present disclosure includes a device including a Si interposer formed over a substrate; HBM and an IC formed over the Si interposer; a heater formed on the Si interposer in a space between the HBM and Si interposer; and one or more temperature sensors in the HBM to monitor a temperature of the HBM.

Aspects include the heater having resistance lines formed on the Si interposer in the space between the HBM and Si interposer. Other aspects include an output of the one or more temperature sensors in the HBM causing activation of the heater directly. Additional aspects include a user operated register formed in the HBM for setting and adjusting a temperature of the HBM. Further aspects include one or more temperature sensors formed in the IC. Yet other aspects include an output of the one or more temperature sensors in the IC causing activation of the heater directly. Still further aspects include wiring formed between the HBM and IC. Other aspects include power and ground connections connected to heater. Additional aspects include the IC including an application specific integrated circuit (ASIC).

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1A schematically illustrates a top view of a conventional device with HBM;

FIG. 1B schematically illustrates an exploded view of the device in FIG. 1A;

FIG. 2 schematically illustrates a top view of a conventional device with HBM connected to an IC;

FIG. 3 schematically illustrates a top view of a device with an integrated heater, in accordance with an exemplary embodiment; and

FIG. 4 schematically illustrates a process flow for dynamic power heating, in accordance with another exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of HBM functionality failure in colder environmental conditions. In accordance with embodiments of the present disclosure, controlled heating is provided at specific device locations to ensure proper functionality during colder environmental conditions.

Methodology in accordance with embodiments of the present disclosure includes forming a Si interposer over a substrate; forming HBM and an IC over the Si interposer; forming a heater on the Si interposer in a space between the HBM and Si interposer; and utilizing one or more temperature sensors in the HBM to monitor a temperature of the HBM.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

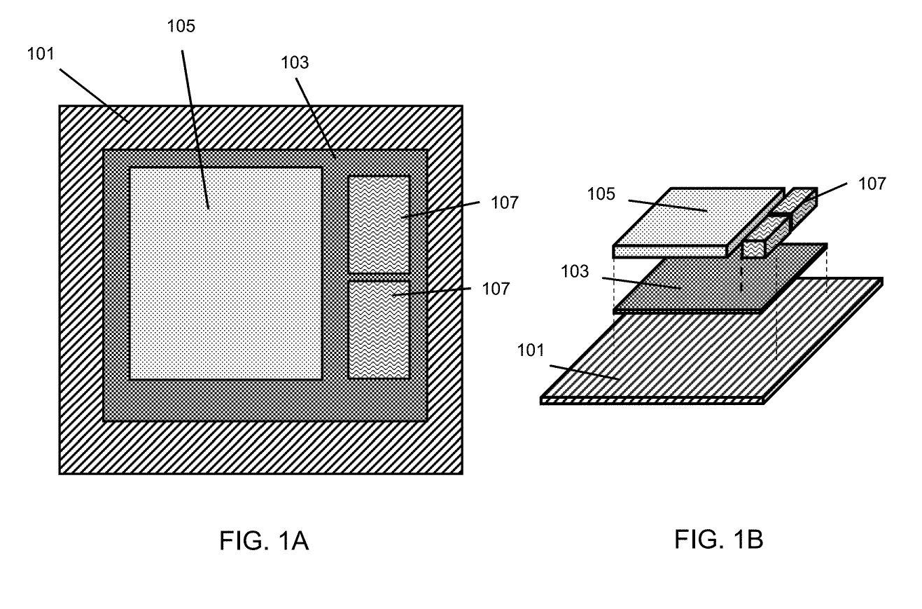

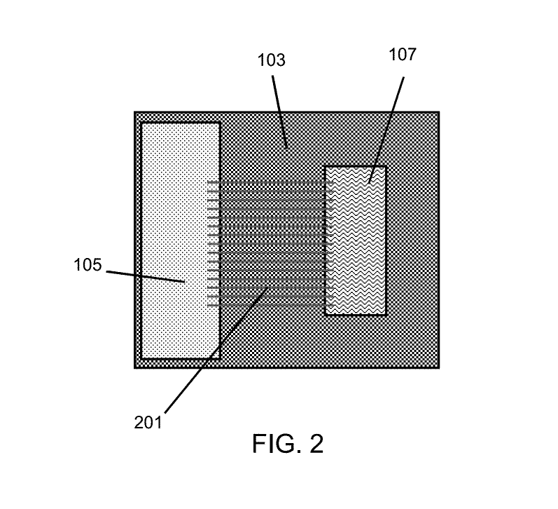

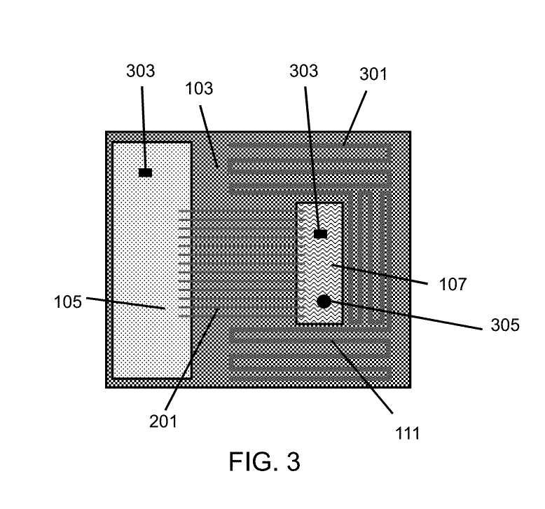

FIG. 3 schematically illustrates a top view of a device with an integrated heater in accordance with an exemplary embodiment. An interposer 103 is disposed over an upper surface of the substrate 101 (FIG. 1A). The IC 105 (e.g., an ASIC) and HBM 107 are disposed over the interposer 103 and connected with signal lines 201. An integrated heater 301 is incorporated in the interposer 103. The present disclosure utilizes the empty space under the HBM 107 on the surface of the interposer 103. The integrated heater in FIG. 3 is formed of resistance lines formed over the empty space under the HBM on the interposer 103. Temperature sensors 303 are included in the device and used to determine if preheating is required. The HBM 107 can have one or more temperature sensors 303, and the IC 105 can have one or more temperature sensors 303. An output of the one or more temperature sensors 303 causes activation of the integrated heater 301 directly. A user operated register 305 can be formed in the HBM 107 for setting and adjusting a temperature of the HBM by a user. Power and ground connections are connected to the integrated heater 301 to supply power to the integrated heater 301.

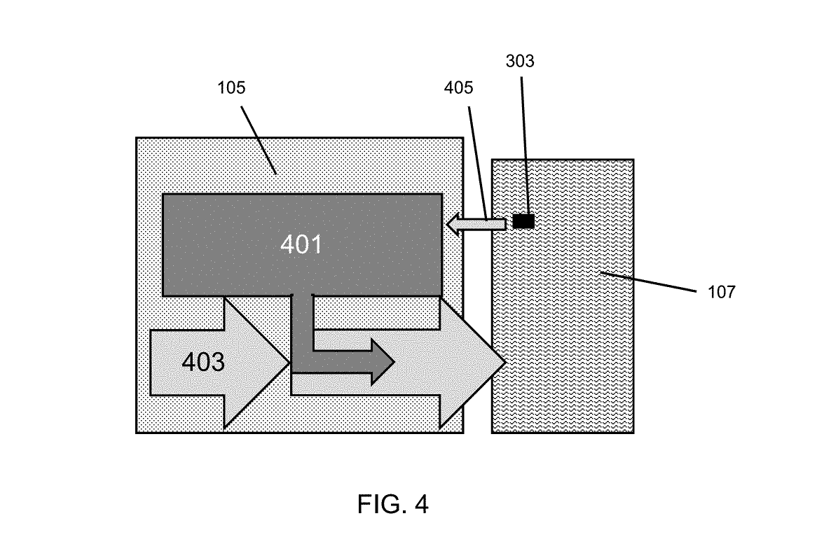

Adverting to FIG. 4, an example of a heating by way of dynamic power with targeted activation is illustrated. The IC 105 can issue functional read/write/idle requests 403 to the HBM 107 as well as dummy reads 401 into targeted quadrants of the HBM 107. By issuing dummy reads 401 in specific dummy patterns in the HBM 107, heat can be generated in targeted areas. Dummy reads 401 can be issued to cool areas of the HBM 107. Cool areas can include areas where the HBM 107 is idle or where bandwidth is not completely utilized. These cool areas then can be heated up by way of the dummy reads to a predetermined operating temperature of the HBM 107. One or more temperature sensors 303 in the HBM 107 can provide up to date information 405 and allow intelligent heating of specific areas of the HBM 107.

The embodiments of the present disclosure can achieve several technical effects, including interposer heater integration to provide controlled and targeted heating. The present disclosure enjoys industrial applicability in any of various industrial applications, e.g., microprocessors, smart phones, mobile phones, cellular towers, cellular handsets, set-top boxes, DVD recorders and players, automotive navigation, printers and peripherals, networking and telecom equipment, gaming systems, and digital cameras. The present disclosure therefore enjoys industrial applicability in any of various types of semiconductor devices using HBM in the advanced technology nodes.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming a silicon (Si) interposer over a substrate;
forming high bandwidth memory (HBM) and an integrated circuit (IC) over the Si interposer;
forming a heater on the Si interposer in a space between the HBM and Si interposer, wherein the heater comprises resistance lines on an upper surface of the Si interposer; and
utilizing one or more temperature sensors in the HBM to monitor a temperature of the HBM.

2. (canceled)

3. The method according to claim 1, wherein an output of the one or more temperature sensors in the HBM causes activation of the heater directly.

4. The method according to claim 3, further comprising:
forming a user operated register in the HBM for setting and adjusting a temperature of the HBM.

5. The method according to claim 1, further comprising:
forming one or more temperature sensors in the IC.

6. The method according to claim 5, wherein an output of the one or more temperature sensors in the IC causes activation of the heater directly.

7. The method according to claim 1, further comprising:
forming wiring between the HBM and IC.

8. The method according to claim 1, further comprising:
connecting the heater to power and ground connections.

9. A method comprising:
forming a silicon (Si) interposer over a substrate;
forming high bandwidth memory (HBM) and an integrated circuit (IC) over the Si interposer;
utilizing one or more temperature sensors in the HBM to monitor a temperature of the HBM; and
generating dummy reads to idle areas of the HBM or non-utilized bandwidth areas of the HBM to generate heat in the idle areas or non-utilized bandwidth areas to a pre-determined temperature.

10. The method of claim 9, further comprising:
providing up to date temperature readings by the one or more temperature sensors to permit intelligent heating of the idle areas or non-utilized bandwidth areas.

11. A device comprising:
a silicon (Si) interposer formed over a substrate;
high bandwidth memory (HBM) and an integrated circuit (IC) formed over the Si interposer;
one or more temperature sensors disposed in the HBM to monitor a temperature of the HBM,
wherein the interface of the HBM is configured to generate dummy reads to idle areas of the HBM or non-utilized bandwidth areas of the HBM to generate heat in the idle areas or non-utilized bandwidth areas to a pre-determined temperature.

12. A device comprising:
a silicon (Si) interposer formed over a substrate;
high bandwidth memory (HBM) and an integrated circuit (IC) formed over the Si interposer;
a heater formed on the Si interposer in a space between the HBM and Si interposer, wherein the heater comprises resistance lines on an upper surface of the Si interposer; and
one or more temperature sensors in the HBM to monitor a temperature of the HBM.

13. (canceled)

14. The device according to claim 12, wherein an output of the one or more temperature sensors in the HBM causes activation of the heater directly.

15. The device according to claim 14, further comprising:
a user operated register formed in the HBM for setting and adjusting a temperature of the HBM.

16. The device according to claim 12, further comprising:
one or more temperature sensors formed in the IC.

17. The device according to claim 16, wherein an output of the one or more temperature sensors in the IC causes activation of the heater directly.

18. The device according to claim 12, further comprising:
wiring formed between the HBM and IC.

19. The device according to claim 12, further comprising:
power and ground connections connected to heater.

20. The device according to claim 12, wherein the IC comprises an application specific integrated circuit (ASIC).
